(19) United States
(12) Patent Application Publication
(10) Pub. No.: US 2019/0071794 A1
(43) Pub. Date: Mar. 7, 2019

(54) EFFICIENT SOLAR GRADE SILICON PRODUCTION SYSTEM

(71) Applicant: SRI International, Menlo Park, CA (US)

(72) Inventors: Jordi Perez Mariano, Los Altos, CA (US); Angel Sanjurjo, Monterey, CA (US); Xiaobing Xie, Foster City, CA (US); Anoop Nagar, Palo Alto, CA (US); Marc Hornbostel, Palo Alto, CA (US)

(21) Appl. No.: 16/119,918

(22) Filed: Aug. 31, 2018

Related U.S. Application Data
(60) Provisional application No. 62/553,160, filed on Sep. 1, 2017.

(51) Int. Cl. C30B 35/00; C30B 29/06; C30B 11/02

(52) U.S. Cl. CPC C30B 35/007; C30B 11/02; C30B 29/06

(57) ABSTRACT

Example systems are described for producing solar grade silicon from a silicon-generating reaction and recycled silicon particles. In one example, a system for manufacturing high purity solid silicon includes a reactor and a cooling chamber. The reactor includes one or more outlets and a reactor chamber. The one or more outlets are configured to receive a silicon tetrahalide, a reducing agent, and recycled silicon particles. The reactor chamber is configured to react the silicon tetrahalide and the reducing agent to produce fresh silicon, a halide salt, and reaction heat. The reactor chamber heats the recycled silicon particles, the fresh silicon, and the halide salt using at least a portion of the reaction heat to form molten silicon and molten halide salt. The molten silicon includes melted fresh silicon and melted recycled silicon particles. The cooling chamber is configured to cool the molten silicon to form the solid silicon.

### RELATED APPLICATION DATA

This application claims priority to U.S. Provisional application No. 62/553,160 filed on Sep. 1, 2017, which is incorporated herein by reference in its entirety.

### GOVERNMENT RIGHTS

This invention was made with government support under contract no. DE-EE-0007550 awarded by the Department of Energy. The government has certain rights in this invention.

### TECHNICAL FIELD

The disclosure relates to silicon manufacturing systems and, more particularly, silicon manufacturing systems for solar grade silicon.

### BACKGROUND

Solar cells are often (e.g., 90%) produced from crystalline silicon substrates. These crystalline silicon substrates typically contain low levels of impurities that may be higher than semiconductor grade silicon and lower than metallurgical grade silicon. Fabrication of solar grade silicon substrates constitutes a significant portion (e.g., about a third) of the cost of solar cells. Currently, there are two main industrial production paths to produce solar grade silicon substrates.

A primary industrial production path for solar grade silicon is through chemical synthesis or variants thereof. However, the rate of production of silicon by the gas/solid reaction of through conventional chemical synthesis processes is limited by a low availability of surface area and a low heat transfer capability of the system. In practice, many reactors are operated in parallel for mass production of silicon resulting in increased capital equipment investment. These capital limitations, in addition to the large energy requirements for this type of process (e.g., over 100 kWh/kg silicon) and the complicated process and reactor design and operation, result in high costs of production. Fluid bed reactors (FBR) may be utilized to lower the energetic and financial cost for solar grade silicon production. However, a significant portion (e.g., up to 15%) of the product of FBR processes is in the form of undesirable superfine Si powders that not only represents a production loss but creates additional costly operational problems.

Another industrial production path for solar grade silicon is through direct selective purification of metallurgical grade silicon to solar grade silicon. With this production path, a large number of production steps may be combined to achieve a minimum desired purity, and the process often still results in a product of marginal purity, high energy input, and relatively high cost-to-purity ratio.

### SUMMARY

In general, this disclosure describes systems and processes for efficiently producing solar grade silicon substrates. Example silicon manufacturing systems are described that use both silicon-generating reactants and solid silicon feedstock to produce solar grade silicon.

In one example, a solar grade silicon manufacturing system includes a reactor that receives silicon tetrahalide and reducing agent reactants. These silicon tetrahalide and reducing agent reactants undergo a highly exothermic reaction to produce silicon and a corresponding halide salt. In parallel, silicon particles are introduced into the reactor and heated by the heat produced from the exothermic reaction. The resulting molten silicon contains both silicon produced from the reaction and silicon introduced as silicon particles and has sufficiently high purity to be used as solar grade silicon feedstock. This solar grade silicon feedstock may be further processed to produce, for example, crystalline silicon substrates for use in solar applications. By using inexpensive solid silicon feedstock with an exothermic silicon-producing reaction to produce high purity silicon, solar grade silicon manufacturing systems as discussed herein may efficiently produce solar grade silicon using less energy and/or lower amount or cost of material input. As such, technical solutions for efficient solar grade silicon manufacturing systems are described.

In some examples, the silicon particles used in the above described process may be recycled silicon. For example, as described above, processing silicon feedstock into crystalline silicon for use in solar panels may produce silicon fines. These silicon fines may be incorporated into the silicon particles to create a self-feeding system. By using recycled silicon fines from silicon feedstock processing as a silicon source to further produce the silicon feedstock used for the silicon wafers, systems described herein may produce less waste and require less silicon from external sources. In another example, the halide salt be incorporated into the silicon particles for use as a heat transfer medium to transfer reaction heat to the silicon of the silicon particles, an oxidation protection layer to protect silicon from reacting with silicon oxide species at high temperatures, and/or a mass transfer medium to etch and remove surface impurities from the silicon particles.

In this way, the silicon manufacturing systems discussed herein may provide technical advantages for manufacturing solar grade silicon in a variety of uses and applications. For example, the reaction heat produced from the exothermic reaction, may supplement or replace reaction-supplied heat for melting and consolidating the silicon particles. As another example, the silicon particles incorporated into the molten silicon may be inexpensive and/or waste products that have a reduced cost or reduce a material input. As yet another example, silicon fines recycled into the silicon particles, alone or with halide salt, may further reduce waste and/or material cost.

In some examples, a system for manufacturing high purity solid silicon includes a reactor and a cooling chamber. The reactor includes one or more outlets and a reactor chamber. The one or more outlets are configured to receive a silicon tetrahalide, a reducing agent, and recycled silicon particles. The reactor chamber is configured to react the silicon tetrahalide and the reducing agent to produce fresh silicon, a halide salt, and reaction heat. The reactor chamber heats the recycled silicon particles, the fresh silicon, and the halide salt using at least a portion of the reaction heat to form molten silicon and molten halide salt. The molten silicon includes melted fresh silicon and melted recycled silicon particles. The cooling chamber is configured to cool the molten silicon to form the solid silicon.

In another example, a method for producing high purity solid silicon includes receiving, by a reaction chamber, a silicon tetrahalide, a reducing agent, and recycled silicon particles and reacting, in the reaction chamber, the silicon tetrahalide and the reducing agent to produce fresh silicon, a halide salt, and reaction heat. The method further includes heating, in the reaction chamber, the recycled silicon particles, the fresh silicon, and the halide salt using at least a portion of the reaction heat to form molten silicon and molten halide salt. The molten silicon includes melted fresh silicon and melted recycled silicon particles. The method further includes cooling, in a cooling chamber, the molten silicon to produce the solid silicon.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a conceptual and schematic diagram illustrating an example system for producing solar grade silicon, in accordance with embodiments discussed herein.

FIG. 2 is a conceptual and schematic diagram illustrating an example system for producing solar grade silicon, in accordance with embodiments discussed herein.

FIG. 3 is a flow diagram illustrating an example technique for producing solar grade silicon, in accordance with embodiments discussed herein.

FIG. 4 is a conceptual and schematic diagram illustrating an example reactor for producing solar grade silicon, in accordance with embodiments discussed herein.

FIG. 5A is a photograph of silicon pellets containing 80% silicon fines and 20% sodium fluoride particles.

FIG. 5B is a photograph of a reaction product surrounded by a graphite layer.

FIG. 5C is a photograph of the reaction product of FIG. 5B from a closer perspective.

FIG. 6A is a photograph of a melt separation product of sodium fluoride ingot (left) and silicon ingot (right).

FIG. 6B is a photograph of the silicon ingot of FIG. 6A.

FIG. 6C is a photograph of a silicon slab formed from the silicon ingot of FIGS. 6A and 6B.

### DETAILED DESCRIPTION

Solar grade polycrystalline silicon feedstock may be grown into a single crystal or a polycrystalline ingot. To fabricate solar grade silicon wafers, the ingot may be shaped, sliced into wafers, grinded, and polished. In these subsequent process steps, a significant portion (e.g., about one third) of the expensive and pure silicon feedstock is lost as waste silicon fines. Recovery of these silicon fines has proven difficult. For example, the silicon fines contain impurities, form porous bodies with low thermal conduction properties, and have surface oxide and hydroxide species that react with core silicon at high temperature to produce silicon monoxide, which further results in silicon losses and operational problems.

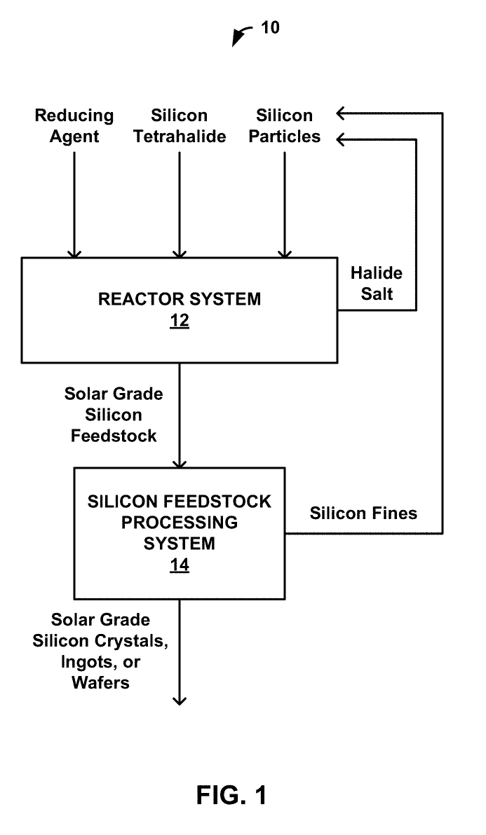

Example silicon manufacturing systems are described that use both silicon-generating reactants and recycled silicon feedstock, such as the silicon fines described above, to produce solar grade silicon. FIG. 1 is a conceptual and schematic diagram illustrating an example system 10 for producing solar grade silicon from a silicon-generating reaction and recycled silicon particles. System 10 includes a reactor system 12 and a silicon feedstock processing system 14. Reactor system 12 is configured to produce solar grade silicon feedstock that incorporate fresh silicon from a silicon generating reaction and recycled silicon from recycled silicon particles. Recycled silicon particles may be any particles that include at least a portion of recycled silicon including, but not limited to silicon fines, silicon pellets, or the like. Solar grade silicon feedstock may include solar grade silicon having any pre-finished form. Silicon feedstock processing system 14 is configured to shape the solid silicon feedstock to create solar grade silicon crystals, ingots, or wafers and recycled silicon particles as a byproduct of shaping the silicon feedstock. As such, system 10 may operate to continuously produce high purity solar grade silicon feedstock with reduced waste, energy input, and material input, as discussed further below.

Reactor system 12 is configured to receive a silicon tetrahalide and a reducing agent as reactants and recycled silicon particles as a supplemental silicon source. Reactor system 12 is configured to react the silicon tetrahalide and the reducing agent to produce fresh silicon, a halide salt, and reaction heat. The reaction between the silicon tetrahalide and the reducing agent may be expressed as follows:

SiX₄+nY→Si+nYX4/n

In the above equation, X represents a halide group, Y represents a reducing agent, n represents the number of stoichiometric moles, and YX represents a halide salt that includes the reducing agent and the halide. For example, a sodium reduction reaction of silicon tetrafluoride may be expressed as follows:

SiF₄(g)+Na(l)→Si(l,s)+4NaF(l,s)ΔH_{298 K}=−164 kcal per mole Si

In the above reaction, the gaseous silicon fluoride (SiF₄) and liquid sodium (Na) react to form highly pure silicon (Si) and sodium fluoride (NaF).

In addition to producing high purity silicon, the silicon tetrahalide reduction reaction is also highly exothermic. This reaction heat is transferred to materials present in the reactor chamber in which the reaction is occurring (and some is lost to the reactor). As such, in addition to heating the fresh silicon and halide salt reaction products, reactor system 12 is configured to heat the co-fed recycled silicon particles present in the reaction chamber above a melting point of silicon using at least a portion of the reaction heat to form molten silicon and molten halide salt. The resulting molten silicon includes both melted fresh silicon produced by the reaction and melted recycled silicon particles. By using the reaction heat to heat and melt the recycled silicon particles, an energy cost of incorporating recycled silicon particles, along with the reaction generated silicon, into silicon feedstock may be reduced.

In addition to synergistically generating silicon and heating co-fed recycled silicon particles with the reaction heat, heating the silicon particles in the presence of a molten halide salt may increase a yield of and/or reduce impurities in the molten silicon. Molten halide salt that is in fluidic contact with silicon particles may aid in heat transfer of the reaction heat to the silicon particles, protect the silicon particles from silicon oxide reactions, and act as an etching medium for removing surface impurities from the silicon particles. For example, silicon may react with water present in the reaction chamber to form silicon dioxide, which may further react with silicon to form silicon monoxide according to the following equation:

Si(s)+SiO₂(s)→2SiO(g)

By heating the silicon particles in the presence of molten halide salt, system 10 may produce solar grade silicon that has a higher purity and yield while using less energy.

Reactor system 12 is configured to cool the molten silicon into solar grade silicon feedstock. Silicon feedstock processing system 14 may receive the solar grade silicon feedstock and shape the solid silicon feedstock to create solar grade silicon crystals, ingots, or wafers. The solar grade silicon crystals, ingots, or wafers may have a high purity suitable for use in photovoltaic cells. For example, the solar grade silicon wafers may have boron and phosphorus impurity concentrations that are less than 0.01 parts per million (ppm) by weight. In some examples, silicon feedstock processing system 14 may include a silicon casting system configured to shape the solid silicon to create solar grade silicon crystals, ingots, or wafers.

In addition to creating the solar grade silicon wafers crystals, ingots, or wafers, silicon feedstock processing system 14 may create waste silicon fines as a byproduct. For example, shaping the silicon feedstock into silicon crystals, ingots, or wafers may involve crushing, cutting, grinding, polishing, abrading, and other processes that produce silicon fines. A silicon fines recycle stream may feed the silicon fines back to reactor system 12 for inclusion into the silicon particles. As such, silicon fines that would otherwise be discarded or put to a lower value use may be incorporated into the solar grade silicon feedstock through a reliable and local supply. In addition to recycling silicon fines, halide salt may be recycled into the silicon particles. For example, as explained above, silicon heated in the presence of molten halide salt may have reduced impurities and/or higher yield. To improve the contact and dispersion of halide salt with the silicon particles, the reactor system 12 may incorporates molten salt into the silicon particles as a protective, purifying binder.

In this way, system 10 may reliably and efficiently produce solar grade silicon crystals, ingots, or wafers with reduced energy input, reduced waste, and/or reduced material input. For example, solar grade silicon feedstock produced herein may have an energy cost for producing 1 kg of silicon of less than 30 kWh/kg with boron and phosphorus impurity levels less than 0.01 ppm weight.

While the systems described herein are useful for manufacturing solar grade silicon, the systems may be used to manufacture other grades of silicon and/or silicon having a variety of levels of purity. In some examples, the systems described herein may be used to manufacture any of metallurgical grade silicon, solar grade electronics grade silicon, semi-conductor grade silicon, or the like. In some examples, the silicon feedstock produced by the example systems and techniques may have a mass fraction of impurities less than 10⁻² (e.g., metallurgical grade silicon), less than 10⁻⁶ (e.g., solar grade silicon), less than 10⁻⁹ (electronics grade silicon), or less than 10⁻¹¹.

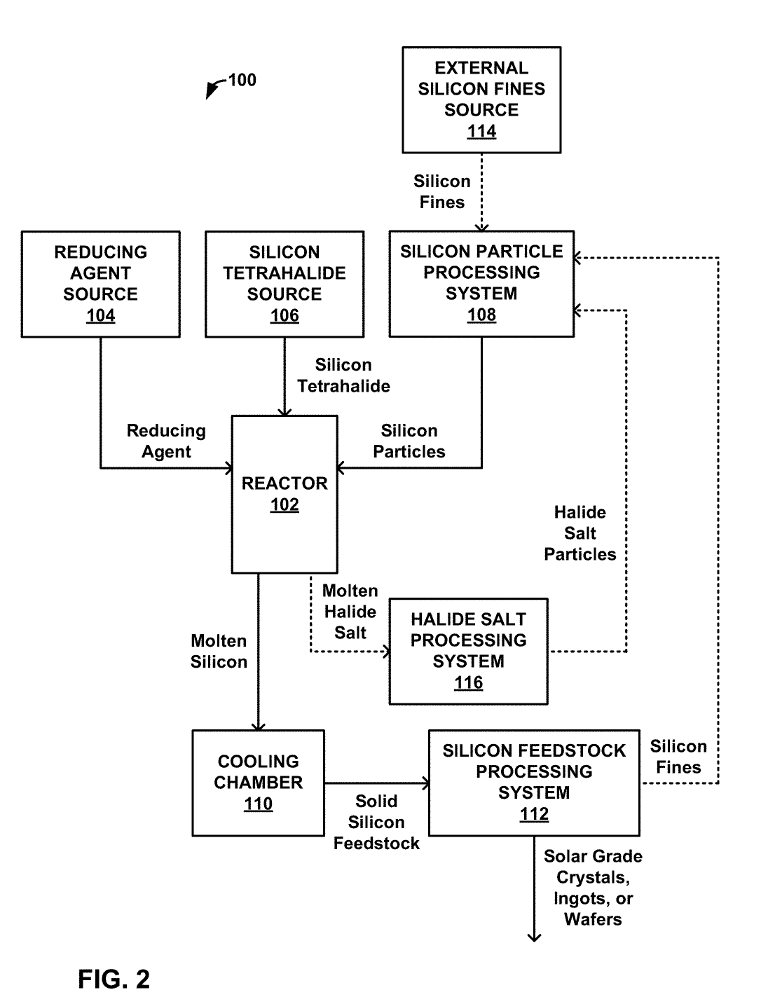

FIG. 2 is a conceptual and schematic diagram illustrating an example system 100 for producing solar grade silicon crystals, ingots, or wafers from a silicon-generating reaction and recycled silicon particles, in accordance with examples discussed herein. Example system 100 includes a reactor 102 and a cooling chamber 110 for producing high purity solar grade silicon feedstock. While shown separately, in some examples, cooling chamber 110 may be part of reactor 102. Example system 100 also includes several optional components including a reducing agent source 104, a silicon tetrahalide source 106, a silicon particle processing system 108, a silicon wafer processing system 112, an external silicon fines source 114, and a halide salt processing system 116.

Reactor 102 is configured to produce high purity molten silicon that includes both fresh silicon from a silicon-generating reaction and recycled silicon from recycled silicon particles. Reactor 102 includes one or more inlets configured to receive, into a reaction chamber, a silicon tetrahalide, a reducing agent, and recycled silicon particles. For example, reactor 102 may include a silicon tetrahalide inlet coupled to silicon tetrahalide source 106 and configured to receive the silicon tetrahalide, a reducing agent inlet coupled to reducing agent source 104 and configured to receive the reducing agent, and a silicon particle inlet coupled to a silicon particle source, such as silicon particle processing system 108, and configured to receive silicon particles. While reactor 102 is shown has having three separate inlets, reactor 102 may have any number of inlets.

Reducing agent source 104 and silicon tetrahalide source 106 are configured to supply a reducing agent and a silicon tetrahalide, respectively, to reactor 102. For example, reducing agent source 104 and silicon tetrahalide source 106 may each include one or more storage tanks and process control instrumentation configured to supply the reducing agent or silicon tetrahalide to reactor 102. In some examples, silicon tetrahalide source 106 may be configured to produce the silicon tetrahalide, such as from its reactants. For example, silicon tetrahalide source 106 may be a silicon tetrafluoride source that includes a reactor configured to precipitate sodium fluorosilicate from fluorosilicic acid and thermally decompose the sodium fluorosilicate to generate silicon tetrafluoride gas for use in reactor 102, as described in U.S. Pat. No. 4,753,783, incorporated in its entirety by reference.

A variety of reducing agents and silicon tetrahalides may be used as reactants for the reaction. Reducing agents that may be used include, but are not limited to, lithium, sodium, potassium, magnesium, strontium, calcium, barium, and the like. Silicon tetrahalides that may be used include, but are not limited to, silicon tetrafluoride, silicon tetrachloride, silicon tetrabromide, silicon tetraiodide, and the like.

In some examples, the reducing agent and the silicon tetrahalide may be selected according to various properties of the reducing agent and/or the silicon tetrahalide including, but not limited to, melting point, boiling point, reactivity, viscosity, cost, and the like. For example, the reducing agent may be a liquid at reactor temperatures, such that the reducing agent may be more easily dispersed into the reaction chamber of reactor 102. As another example, the reducing agent and/or silicon tetrahalide may be relatively inexpensive.

In some examples, the reducing agent and silicon tetrahalide are selected according to properties of the reaction between the reducing agent and the silicon tetrahalide and/or properties of the halide salt produced from the reaction between the reducing agent and the silicon tetrahalide including, but not limited to, a reaction heat, melting point, boiling point, surface tension, density, viscosity, and the like. For example, various properties of the halide salt may be useful for separating the halide salt from the silicon, wetting the silicon particles, treating a surface of the silicon particles, and the like, such that the reducing agent and silicon tetrahalide may be selected to produce a halide salt having these properties.

In some examples, the reducing agent and silicon tetrahalide are selected such that the resulting halide salt has a melting point less than about 1200° C. As described above, at high temperatures (e.g., greater than about 1200° C.), silicon may react with water present in the reaction chamber to form silicon dioxide, which may further react with silicon to form silicon monoxide, or may react with the walls of the reaction chamber of reactor 102. By including a halide salt that is a liquid at these high temperatures, the halide salt may coat silicon in reactor 102 to reduce or substantially eliminate reactions in which the silicon particles form silicon oxides.

In some examples, the reducing agent and silicon tetrahalide are selected such that the resulting halide salt has a density that is less than the density of molten silicon. As will be described further below, differences in density between the molten silicon and molten halide salt may be used to separate the silicon and halide salt, either in solid form, liquid form, or a mixture of solid and liquid forms. For example, molten sodium halide may have a density of less than about 2 g/cm³ at 1420° C., while molten silicon may have a density of greater than 2.5 g/cm³. Molten silicon droplets may sink to a bottom of the reaction chamber and coalesce into a pool, leaving molten sodium halide in a top layer.

In some examples, the reducing agent and silicon tetrahalide are selected such that the resulting molten halide salt has a surface energy that is less than molten silicon. For example, molten silicon may have a surface energy that is about 850±50 ergs/cm² at 1000° C., while sodium fluoride may have a surface energy that is about 185 ergs/cm² at 1000° C. As such, the higher surface energy of molten silicon may aid the molten silicon in coalescing to form a pool of molten silicon. Additionally or alternatively, the difference in surface energy may aid in continuous separation of the molten silicon from the molten halide salt, as will be described further below.

Additionally, molten halide salt may provide other heat transfer and/or surface treatment benefits to silicon in reactor 102. For example, molten halide salt that is in fluidic contact with silicon particles may aid in heat transfer of reaction heat to the silicon particles, as heat may be transferred more efficiently to solid silicon particles from a liquid phase than a gaseous phase. As another example, molten halide salt may act as an etching and transfer medium for removing surface impurities from the silicon particles. For example, molten silicon fluoride may keep the surface of the molten silicon clean by etching and dissolving any oxide film as fluorosilicate.

In some examples, as will be illustrated further in the Experimental Methods, the reducing agent may be sodium and the silicon tetrahalide may be silicon tetrafluoride. Sodium has a melting point of about 98° C., such that sodium may be transported and dispersed into reactor 102 as a liquid without significant heating. Silicon tetrafluoride has a boiling point of −86° C., such that silicon tetrahalide may be transported as a gas and used to pressurize reactor 102. Gaseous silicon tetrahalide and liquid sodium may undergo a reduction reaction to form silicon and sodium fluoride. Sodium fluoride has a variety of favorable characteristics including, but not limited to, a relatively low surface energy, low viscosity, ability to dissolve silicon dioxide, low reactivity with silicon, and good heat transfer capability. Silicon has a melting point of 1414° C. In contrast, sodium fluoride has a melting point of 993° C. As such, sodium fluoride may be a liquid, and thus available for wetting and etching, at temperatures in which silicon is most susceptible to reaction with silicon dioxide to form silicon monoxide. As discussed above, molten silicon halide may have a lower density and lower surface energy than molten silicon, such that molten silicon may coalesce to form a pool of molten silicon at a bottom of the reaction chamber of reactor 102, while continuing to be wetted by the molten silicon halide. Further, the reaction may be highly exothermic (e.g., −140 kcal/mol of silicon tetrafluoride reacted), such that the adiabatic temperature of the silicon tetrafluoride and sodium system may be greater than 2000° C. and the adiabatic temperature of the system consisting of silicon tetrafluoride, sodium, and silicon particles may be greater than 1700° C., each of which are well above the melting point of silicon (1414° C.). As such, the reaction heat produced from the reaction of silicon tetrahalide and sodium may supply a substantial portion of the heat required to melt the fresh silicon, recycled silicon particles, and halide salt for coalescence of the silicon and separation of the silicon from the sodium fluoride.

System 100 also includes a silicon particle source configured to supply recycled silicon particles to reactor 102. In the example of system 100, the silicon particle source is silicon particle processing system 108; however, any system that supplies reactor 102 with recycled silicon particles may be used.

In addition to one or more inlets for introducing the silicon tetrahalide, the reducing agent, and the silicon particles, reactor 102 may include one or more inlets for other components, such as inert gases. For example, reactor 102 may be coupled to an inert gas source used to convectively heat, pressurize, and/or purge a reaction chamber of reactor 102.

Reactor 102 is configured to react the silicon tetrahalide and the reducing agent to produce fresh silicon, a halide salt, and reaction heat. Reactor 102 may react the silicon tetrahalide and the reducing agent by providing an environment in which the silicon tetrahalide and the reducing agent may undergo a reduction reaction. As such, reactor 102 may be configured to control reaction conditions, such as temperature, pressure, flow rate, and other conditions associated with reaction kinetics to facilitate the reaction between the reducing agent and the silicon tetrahalide.

Reactor 102 is configured to heat the recycled silicon particles, the fresh silicon, and the halide salt using at least a portion of the heat generated by the reaction to form molten silicon and molten halide salt. Reactor 102 may heat the recycled silicon particles using at least the portion of the reaction heat by containing the recycled silicon particles in thermal proximity to the reduction reaction, the reduction reaction products, or heat transfer structures of reactor 102 such as walls, such that reaction heat from the reduction reaction within reactor 102 is at least partially transferred to the recycled silicon particles. For example, reactor 102 may be configured to introduce and contain the silicon tetrahalide, the reducing agent, and the recycled silicon particles in a same reaction chamber, such that the recycled silicon particles are proximate to the silicon tetrahalide, the reducing agent, the fresh silicon, and/or the halide salt as the reaction is taking place and producing reaction heat. As another example, reactor 102 may be configured to introduce the recycled silicon particles to another chamber of reactor 102, such as a product chamber containing the fresh silicon and halide salt, such that the reaction products heat by the reaction heat may further may heat to the silicon particles. The resulting molten silicon includes newly produced, melted silicon from the silicon-generating reaction and melted recycled silicon from the recycled silicon particles.

In addition to heating the recycled silicon particles, the fresh silicon, and the halide salt using reaction heat, reactor 102 may be configured to heat any of the silicon tetrahalide, the reducing agent, the recycled silicon particles, the fresh silicon, and/or the halide salt using other heat sources. For example, the reaction heat may not supply all the heat to melt the fresh silicon, the recycled silicon particles, and the halide salt, as a melting point of silicon is 1414° C. As such, reactor 102 may include other heating sources configured to supply heat to the reaction chamber of reactor 102, such as heating elements for heating walls of the reaction chamber or preheat sources for heating one or more of the reactants before introduction into the reaction chamber.

To reduce unwanted reactions with components of reactor 102, internal walls of the reaction chamber of reactor 102 may be constructed from inert materials capable of operating at high temperatures (e.g., up to 1600° C.) in the presence of the silicon tetrahalide, the reducing agent, silicon, and the halide salt, such that the reactor materials have a reduced likelihood of contaminating the molten silicon. For example, at high temperatures, impurities in the materials of the reactor walls, such as boron and phosphorus, may leach into the molten silicon. Examples of materials with a reduced likelihood of contaminating silicon may include, but are not limited to, graphite, SiC, SiNx, or the like. Other materials used to construct reactor 102 include materials with high thermal conductivity and high resistance to oxidation at high temperatures, such as Inconel, nickel, stainless steel, and the like. In some examples, reactor 102 may include multiple layers, such as an inner graphite layer contacting the reactants and products and an outer Inconel layer transferring heat to the reaction chamber.

Reactor 102 may include one or more outlets configured to discharge molten silicon and/or molten halide salt from the reaction chamber of reactor 102. Reactor 102 is configured to output molten silicon to cooling chamber 110. In some examples, reactor 102 may include immiscible liquid-liquid separation equipment configured to separate molten silicon from molten halide salt, such that molten silicon and molten halide salt may be separately discharged from reactor 102. In some examples, the molten silicon and molten halide salt may be separated due to a difference in surface tension, such as through coalescence. For example, the molten halide salt may have a significantly lower surface tension than molten silicon. As such, reactor 102 may include a porous or perforated container that contains the higher surface tension silicon and discharges the lower surface tension halide salt through the pores or perforations, as described in U.S. Pat. No. 4,753,783, incorporated in its entirety by reference. In some examples, the molten silicon and molten halide salt may be separated due to a difference in density, such as through gravity settling. For example, molten silicon may have a higher density and surface tension than molten halide salt, such that molten silicon droplets may coalesce into a single pool at a bottom of the reaction chamber of reactor 102. As such, molten silicon may be removed from an outlet at a lower position of reactor 102 while molten halide salt may be removed from an outlet at a higher position of reactor 102.

Cooling chamber 110 is configured to receive the molten silicon from reactor 102 and cool the molten silicon to form solid silicon feedstock, such as through active or passive cooling. In some examples, cooling chamber 110 includes equipment for cooling the molten silicon, such as heat exchangers, coolers, fans, air streams, and the like. In some examples, cooling chamber 110 includes a crystal growth unit for casting the molten silicon into crystalline feedstock or crystals. For examples, a crystal growth unit may include crucibles for containing the molten silicon, seeding equipment for seeding the molten silicon, and cooling equipment for cooling the molten silicon in stages to form crystallized silicon feedstock. In this way, cooling chamber 110 may allow the molten silicon to solidify and crystallize. In some examples, cooling chamber 110 may be configured to receive small amounts of molten halide salt, such that the molten halide salt continues to wet surfaces of the molten silicon as the molten silicon cools. For example, molten silicon may contain impurities that may be removed by molted halide salt in contact with the molten silicon, which acts as a thermodynamic sink and provides a path for further removal of impurities. In other examples, this casting may take place in, for example, silicon feedstock processing system 112.

While the separation of molten silicon and molten halide salt has been described as a continuous process, in some examples, the silicon may be separated from the halide salt in a batch process. For example, both the molten silicon and the molten halide salt may be cooled into a solid ingot containing both the silicon and the halide salt. The solid silicon and solid halide salt may be broken apart, such as through mechanical fracturing, to separate the silicon from the halide salt. The separated silicon may be further purified, such as through washing remaining halide salt from the silicon.

In this way, system 100 may be used to produce high purity silicon feedstock from a silicon producing reaction and recycled silicon particles. System 100 may further include a silicon feedstock processing system 112, such as described for silicon feedstock processing system 14 of FIG. 1. Silicon feedstock processing system 112 is configured to shape the solid silicon to create solar grade silicon crystals, ingots, or wafers. The resulting solar grade silicon crystals, ingots, or wafers may have high purity, such as at least grade IV shown below. For example, the described solar grade silicon crystals, ingots, or wafers may have any of concentrations in the table below:

| | Silicon Grade Category | | | |
|---|---|---|---|---|
| | I | II | III | IV |
| Boron | <1 parts per | <20 ppba | <300 ppba | <1000 ppba |
| Aluminum | billion atoms | | | |
| | (ppba) | | | |
| Phosphorus | <1 ppba | <20 ppba | <50 ppba | <720 ppba |
| Arsenic | | | | |
| Antimony | | | | |
| Titanium | <10 ppba | <50 ppba | <100 ppba | <200 ppba |
| Chromium | (total) | (total) | (total) | (total) |
| Iron | | | | |
| Nickel | | | | |
| Copper | | | | |
| Zinc | | | | |
| Molybdenum | | | | |
| Sodium | <10 ppba | <50 ppba | <100 ppba | <4000 ppba |
| Potassium | (total) | (total) | (total) | (total) |
| Calcium | | | | |
| Carbon | <0.3 parts per | <2 ppma | <5 ppma | <100 ppma |
| | million atoms | | | |
| | (ppma) | | | |

System 100 may be configured to recycle silicon waste and/or halide salt into reactor 102 for use in producing solar grade silicon feedstock, crystals, ingots, or wafers. Silicon feedstock processing system 112 may be configured to feed recycled silicon fines to silicon particle processing system 108. As discussed with respect to silicon feedstock processing system 14 of FIG. 1, silicon feedstock processing system 112 may produce silicon fines as a byproduct of creating silicon wafers. Once treated, these silicon fines may have a high purity as the silicon feedstock from which they are derived. For example, recycled silicon particles formed from the recycled silicon fines may have boron and phosphorus concentrations less than 0.01 ppm weight. To recycle these high purity silicon fines, system 110 includes a silicon fines recycle stream configured to feed the silicon fines from silicon feedstock processing system 112 to silicon particle processing system 108. In this way, silicon waste generated from the high purity silicon feedstock described above may be recycled back into reactor 102.

Silicon particle processing system 108 may be configured to receive recycled silicon fines from silicon feedstock processing system 112, create recycled silicon particles from the recycled silicon fines suitable for use in producing solar grade silicon, and feed the recycled silicon particles to reactor 102. As such, silicon particle processing system 108 may include a variety of pretreatment and shaping processes to create the recycled silicon particles from recycled silicon fines.

In some examples, silicon particle processing system 108 includes a pelletizer configured to pelletize recycled silicon fines to form the silicon particles. For example, recycled silicon fines may have a small size with a very high surface to volume ratio. Such small recycled silicon fines may be especially susceptible to reactions with silicon dioxide at high temperatures. As such, the recycled silicon fines may be formed into larger silicon pellets that have a lower surface to volume ratio. In some examples, the recycled silicon particles may include a binder, such as the halide salt, to wet the silicon, protect the silicon from reaction with silicon dioxide, and aid in heat transfer. For example, as discussed above, the molten halide salt may act as a heat transfer medium to promote heat transfer with the silicon, as a wetting medium to protect the silicon from reacting with silicon dioxide at high temperatures, and etching medium to remove surface impurities from the silicon particles. As such, the pelletizer may be configured to receive a binder, such as the halide salt, and pelletize the recycled silicon fines with the binder to form the silicon particles. The halide salt may be dispersed with the recycled silicon fines, such that the molten halide salt may more quickly wet the recycled silicon fines upon entry into reactor 102. In some examples, the silicon fines and the molten salt particles are pelletized at a molar ratio of about 2:1 to about 5:1. Silicon particle processing system 108 may be configured to transport the recycled silicon particles to at least one of the inlets of reactor 102, such as by using a conveyer or other particle transport system. In some examples, the recycled silicon particles may have a largest dimension between about 10 nm and about 10 mm. For example, silicon fines may be between about 10 nm and about 1 mm, while silicon pellets may be between about 1 mm and 10 mm.

In some examples, silicon particle processing system 108 includes a pretreatment system configured to purify the recycled silicon fines by removing impurities from the recycled silicon fines. For example, recycled silicon fines that are produced from a cutting environment, such as part of silicon feedstock processing system 112, may include contamination by metallic species from wires, diamond and silicon carbide particles from cutting blades or slurries, surfactant, anticorrosion, and dispersant species, and surface oxide and hydroxide species. As such, silicon particle processing system 108 may include one or more apparatuses to remove these contaminants from recycled silicon fines before incorporating the recycled silicon fines into the silicon particles. In some examples, the pretreatment system is configured to remove impurities through at least one of etching, selective oxidation, acid leaching, and washing.

In some examples, system 100 includes an external silicon fines source 114 configured to supply silicon fines to silicon particle processing system 108. For example, silicon fines waste may be collected from sources outside the silicon production process described above. As an example, recycled silicon fines from a fluidized bed reactor (FBR) may be used as silicon fines for the silicon particles. The FBR silicon fines may have, for example, porous agglomerates containing a mixture of crystalline, amorphous, and hydrogenated silicon species having a variety of micron and submicron sizes and high internal porosity that render them unsuitable for many melt consolidation processes. These silicon fines may be pretreated, as explained above, to remove various impurities from the silicon fines. Further, during the formation of the molten silicon, remaining impurities in the molten silicon may be transferred to the molten halide salt. As such, external silicon fines source 114 may provide an inexpensive source of silicon for use in the silicon particles. Thus, system 100 may utilize recycled silicon fines from within system 100, from external silicon fines source 114, or mixtures thereof.

In some examples, system 100 includes a halide salt processing system 116. Halide salt processing system 116 may be configured to receive halide salt from reactor 102 and supply halide salt to silicon particles processing system 108. For example, as described above, the molten halide salt may be incorporated into the recycled silicon particles. As such, halide salt processing system 116 may process the molten halide salt for use in the recycled silicon particles. In some examples, halide salt processing system 116 provides molten halide salt to silicon particle processing system 108, such that the molten halide salt cools around the recycled silicon fines. In some examples, halide salt processing system 116 processes the molten halide salt into a powder, such as by cooling and crushing, dissolves or suspends the halide salt into a solvent to form a slurry, and recrystallizes the dissolved or suspended halide salt to produce silicon halide particles. Silicon particles processing system 108 may mix the silicon halide particles with the silicon fines to form the silicon particles.

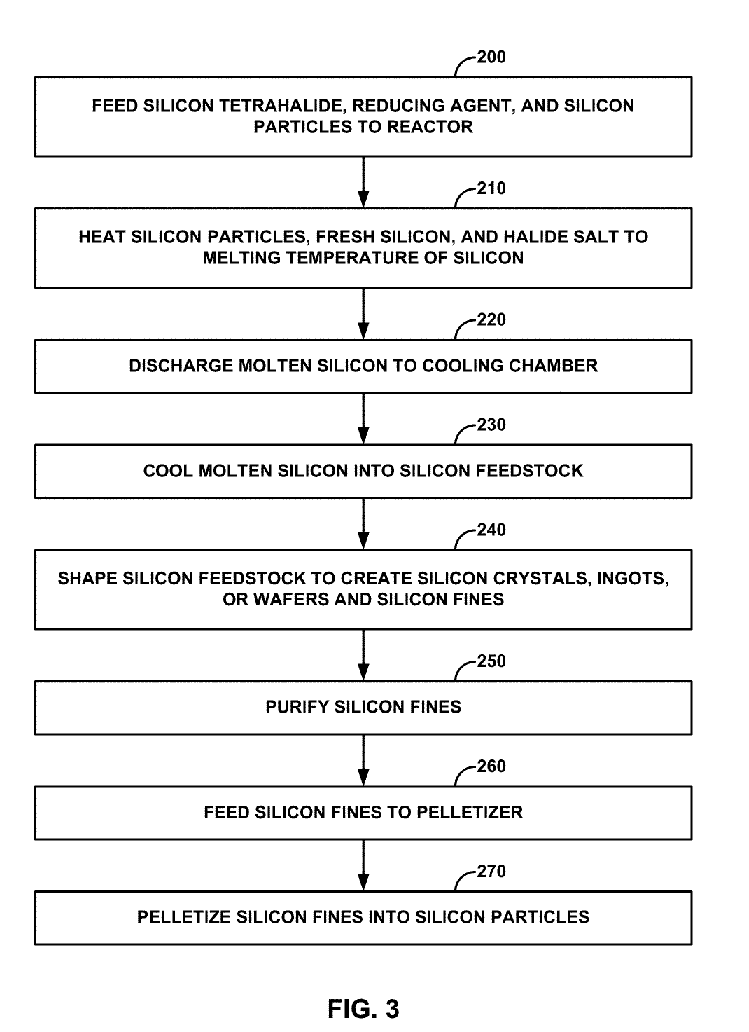

FIG. 3 is a flow diagram illustrating an example technique for producing solar grade silicon crystals, ingots, or wafers, in accordance with examples discussed herein. The techniques of FIG. 3 will be described with respect to system 100 of FIG. 2; however, it will be understood that other systems may implement the techniques of FIG. 3. For purposes of explanation, the technique of FIG. 3 is illustrated as proceeding sequentially through various steps 200-270; however, it will be understood that the principles of the technique of FIG. 3 may be applied to a continuous process, a semi-continuous process, or a batch process, such that any of the steps of FIG. 3 may be occurring simultaneously or in an alternative order. Further, any aspect of the technique of FIG. 3 may be controlled by a process control system. For example, equipment discussed in FIG. 2 and used to perform the technique of FIG. 3 may be communicatively coupled to one or more controllers and/or control systems and configured to receive process control measurements and send process control signals.

In some examples, such as a batch process or start-up of a continuous process, the technique includes preheating reactor 102 to an ignition temperature of a reducing agent. For example, in a process that utilizes silicon tetrafluoride and sodium, reactor 102 may be heated to above 600° C.

The technique includes feeding, into reactor 102, a silicon tetrahalide, a reducing agent, and recycled silicon particles (200). For example, the technique may include feeding the silicon tetrahalide from a silicon tetrahalide source, the reducing agent from a reducing agent source, and the recycled silicon particles from a recycled silicon particle source. In some examples, the silicon tetrahalide is fed into reactor 102 to maintain a predetermined pressure of reactor 102, such as about 1 atm. Once reactor 102 reaches a predetermined temperature, such as the ignition temperature of the reducing agent, the reducing agent may be fed into reactor 102. The reducing agent and/or the recycled silicon particles may be fed into reactor 102 continuously or in pulses. For example, the reducing agent may be added in pulses, and the recycled silicon particles may be added continuously or before, during, or after the reducing agent pulses. In some examples, the reducing agent includes at least one of lithium, sodium, potassium, and magnesium. In some examples, the silicon tetrahalide is silicon tetrafluoride.

The technique includes reacting, in the reaction chamber, the silicon tetrahalide and the reducing agent to produce fresh silicon, a halide salt, and reaction heat. Reactor 102 may maintain the silicon tetrahalide and the reducing agent in fluidic contact in a reaction chamber, such that the silicon tetrahalide and the reducing agent react with each other to form fresh silicon and halide salt. As such, the technique may include reacting the silicon tetrahalide and the reducing agent by maintaining reactor conditions, such as a pressure range or minimum temperature, so that the reaction progresses. For example, a controller coupled to any of the inlets to reactor 102, temperature instrumentation, pressure instrumentation, and/or flow instrumentation may monitor the flows of the silicon tetrahalide, reducing agent, or silicon particles, the temperature of reactor 102, and the pressure of reactor 102.

As the reducing agent gets sufficiently hot, it reacts vigorously with the silicon tetrahalide according to the reaction below:

SiX₄+4Y+nSi→(1+n)Si+4YX

In the above equation, X represents the halide, Y represents the reducing agent, n represents a number of moles of recycled silicon from silicon particles, and YX represents the halide salt that includes the reducing agent. The Gibbs energy of the reaction between the silicon tetrahalide and the reducing agent may be between about −400 kJ and about −600 kJ, depending on the silicon tetrahalide and reducing agent used. In some examples, this reaction heat may be sufficient to melt at least a portion of the silicon and/or halide salt, depending on an amount of recycled silicon particles used. For example, for solid silicon particles, as the number of moles of silicon from recycled silicon particles increases, the amount of heat required to melt the recycled silicon particles increases.

The technique includes heating the recycled silicon particles, the fresh silicon, and the halide salt to the melting temperature of silicon to form molten silicon and molten halide salt (210). As discussed above, for the fresh silicon and the recycled silicon particles to consolidate and be subsequently separated from the halide salt, the fresh silicon and recycled silicon particles may be melted into molten silicon. Due to the thermal proximity of the recycled silicon particles to the reaction in reactor 102, this heating includes heating the recycled silicon particles, the fresh silicon, and the halide salt using at least a portion of the reaction heat generated by the reaction of the silicon tetrahalide and reducing agent. The molten silicon includes melted fresh silicon and melted recycled silicon particles. It is to be understood that when reactor 102 is said to be heated to a particular temperature, the actual temperature within reactor 102 may fluctuate.

In some examples, the technique includes heating the reaction chamber to a first temperature prior to receiving the reducing agent. The first temperature may be between a melting point of the reducing agent and a melting point of the silicon, such that the reaction mixture may be a two-phase system. The technique may further include heating the silicon particles, the fresh silicon, and the halide salt to a second temperature above the melting point of the silicon.

In some examples, reactor 102 may heat the fresh silicon and/or recycled silicon particles to the melting temperature in situ. For example, heating elements of reactor 102 may apply heat to the reaction mixture of recycled silicon particles, fresh silicon, and halide salt so that the reaction mixture reaches at or above the melting temperature of silicon. In the example of a batch reaction, reactor 102 may hold the reaction mixture at or above the melting temperature for a period of time sufficient for at least a portion of the molten silicon from the recycled silicon particles and fresh silicon to consolidate and/or coalesce into a pool. In the example of a continuous reaction, reactor 102 may continuously heat added reaction mixture for a residence time sufficient for at least a portion of the silicon from the recycled silicon particles and fresh silicon to consolidate and/or coalesce into a pool. In some examples, the period of time and/or residence time may be greater than 10 minutes. In some examples, reactor 102 may heat the fresh silicon and/or recycled silicon particles to the melting temperature in a separate chamber of reactor 102, such as a graphite crucible. For example, the recycled silicon particles and fresh silicon may be loaded into a graphite crucible and heated in a silicon melting furnace.

The technique includes discharging, from reactor 102, the molten silicon to cooling chamber 110 (220). In some examples, discharging the molten silicon from reactor 102 may involve separating the molten silicon from the molten halide salt. As such, any one or more of a variety of separation techniques may be used including, but not limited to, coalescence, gravity settling, or any other separation technique suitable for separating immiscible molten silicon from molten halide salt.

The technique includes cooling, in cooling chamber 110, the molten silicon to produce the solid silicon feedstock (230). For example, a cooling system of cooling chamber 110 may introduce an inert gas to cooling chamber 110 or a cooling medium through a heat exchanger in cooling chamber 110. In some examples, the technique includes crystallizing the molten silicon. For example, cooling chamber 110 may include equipment for seeding and crystallizing the molten silicon to form crystalline silicon feedstock. In some examples, the technique includes cooling the molten silicon to a temperature that is less than the melting point of the silicon and greater than the melting point of the halide salt prior to removing the molten halide salt.

The technique includes shaping the solid silicon to create solar grade silicon crystals, ingots, or wafers, and the silicon fines (240). For example, silicon feedstock processing system 114 may cut the silicon feedstock into high purity silicon wafers. This cutting may create the recycled silicon fines, as described above. The technique includes purifying the recycled silicon fines (250). For example, silicon particle processing system 108 may remove impurities from the recycled silicon fines, such as impurities introduced during shaping of the solid silicon. In some examples, purifying the recycled silicon fines includes at least one of etching, selective oxidation, acid leaching, or washing.

The technique includes feeding the purified recycled silicon fines to the pelletizer (260). For example, a screw conveyer or other device or system may transport the purified recycled silicon fines to the pelletizer. The technique includes pelletizing recycled silicon fines to form the recycled silicon particles (270). In some examples, the technique includes pelletizing the recycled silicon fines with a binder comprising halide salt particles to form the recycled silicon particles. The recycled silicon fines and the molten salt particles may be pelletized at a molar ratio of about 2:1 to about 5:1.

Experimental Methods

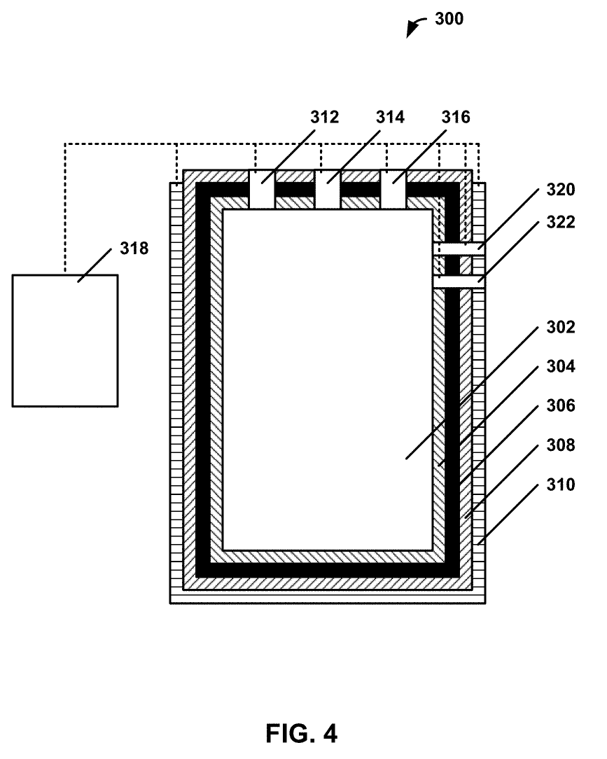

FIG. 4 is a conceptual and schematic diagram illustrating an example reactor for producing solar grade silicon, in accordance with embodiments discussed herein. Reactor 300 may include a gas-tight cylindrical chamber 308 made of Inconel, a nickel layer 306 on an inside of chamber 308, and a graphite layer 304 on an inside of nickel layer 306. Chamber 308 may be surrounded by heating element 310, such as heating coils on sides of chamber 308 and a hot plate on a base of chamber 308. Reactor 300 may include a silicon tetrafluoride inlet 312 coupled to silicon tetrafluoride gas cylinders, a sodium inlet 314 coupled to a liquid sodium tank, and a silicon particle inlet 316 coupled to a hopper. Reactor 300 includes temperature instrumentation 320 and pressure instrumentation 322 to monitor pressure of silicon tetrafluoride in chamber 308. Heating element 310, silicon tetrafluoride inlet 312, sodium inlet 314, silicon particle inlet 316, temperature instrumentation 320, and pressure instrumentation 322 may be communicatively coupled to a controller 318 configured to receive process control data and send process control commands. Controller 318 may be a single controller or multiple controllers.

In operation, heating element 310 heated reactor 300 to above an ignition temperature of sodium (e.g., about 600° C.). Silicon tetrafluoride was introduced to chamber 308 to maintain a pressure at about 1 atm. Liquid sodium at 120° C. was introduced to chamber 308 through sodium inlet 314 in pulses to heat reactor 300. Once reactor 300 reached a target temperature, silicon particles were introduced into chamber 308 through silicon particle inlet 316 in pulses. The sodium and silicon particles were added to reactor 300 in pulses until the silicon particles were used up, after which residual silicon tetrafluoride gas was removed from chamber 308 and chamber 308 was purged with argon and allowed to cool to room temperature.

The reaction product included silicon fines, fresh silicon, and sodium fluoride. To separate the silicon from the sodium fluoride, the reaction products were transferred to a graphite crucible in a high temperature furnace and heated to about 1420° C., which caused molten silicon droplets to coalesce into a single pool, such that the molten silicon and molten sodium fluoride phases were immiscible. The temperature was held at 1420° C. for 20 minutes, after which the crucible was cooled, and the product collected. The silicon ingot was separated from the sodium fluoride using mechanical fracturing. The silicon ingot was washed with deionized water to remove surface impurities.

The following Examples 1-9 were performed generally using some or all of the method of FIG. 4 described above, except where indicated.

### Example 1

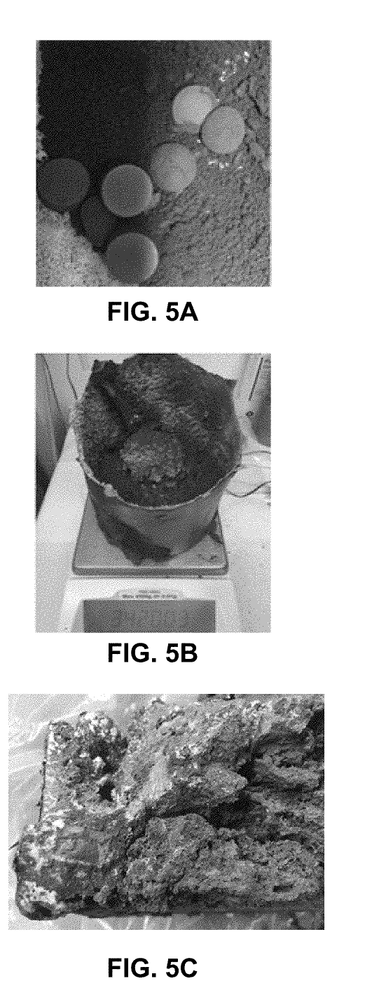

Fluidized bed reactor (FBR) silicon fines waste, a byproduct from the production of silicon by pyrolysis of silane in industrial fluid bed reactors, were mixed with sodium fluoride particles in a 4:1 ratio and pelletized into silicon pellets. FIG. 5A is a photograph of the silicon pellets containing 80% silicon fines and 20% sodium fluoride particles. The pellets were fed into reactor 300 during the silicon fluoride/sodium reaction, as generally described in FIG. 4 above. However, in this example, the external walls of reactor 300 were pre-heated to 450° C. and the pressure of SiF₄ in the reactor was slightly higher than 1 atm.

The reaction product was greyish brownish, and although the added pellets of silicon fines were incorporated into the products, the cylindrical profiles of the pellets could still be discerned in the product. XRD detected crystalline phases consisting mainly silicon and sodium fluoride.

### Example 2

The external walls of the reactor were preheated to a temperature of 600° C. The same silicon fines/sodium fluoride pellets used in Example 1 were co-fed with sodium into reactor 300. The reaction after each pulsed addition was fast (a few minutes) and zones of the external wall temperature increased to over 800° C. because of the heat released from the reaction. For each pulsed addition of reactants including the feeding of silicon particles, the total reaction per pulse took just a few minutes to be completed. After several pulsed additions, both brown lava-like globular formations and metallic powders could be seen in the reaction product, and most of the pellets of silicon fines had been incorporated into the products and the sodium fluoride melted and filled the pores in its vicinity. FIG. 5B is a photograph of a reaction product surrounded by a graphite layer. FIG. 5C is a photograph of the reaction product of FIG. 5B from a closer perspective. As seen in FIG. 5C, pellets may be discernible in the reaction product.

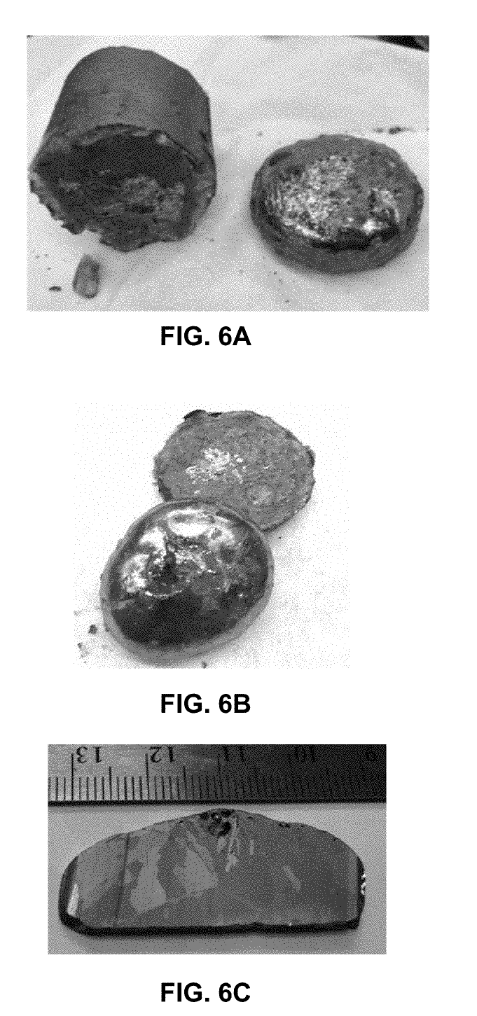

FIG. 6A is a photograph of a melt separation product of sodium fluoride ingot (left) and silicon ingot (right). FIG. 6B is a photograph of the silicon ingot of FIG. 6A. As seen in FIG. 6B, there is a thin layer of sodium fluoride between the silicon and the graphite, such that the silicon is protected from reactions with the graphite. FIG. 6C is a photograph of a silicon slab of the silicon ingot of FIGS. 6A and 6B. The XRD spectrum of the products showed only Si and NaF peaks.

Representative samples of this product were then loaded in a different graphite crucible and heated to 1420° C. for 20 minutes to simulate the operation at higher temperatures. All silicon fines had coalesced and resulted into a unique rounded ingot similar to the silicon ingots shown in FIG. 6A-6C. The concentrations of boron and phosphorus in the silicon were below 0.1 ppm weight and the concentrations of transition metals were even lower, as seen below. Detailed analysis and representative analysis are given in Table 1 below.

TABLE 1

| | Sample #1 | Sample #2 | | Sample #1 | Sample #2 |
|---|---|---|---|---|---|
| Impurity | (ppm) | (ppm) | Impurity | (ppm) | (ppm) |
| Boron | 0.034 | 0.040 | Iron | 1.6 | 1.0 |
| Phosphorus | 0.035 | 0.028 | Cobalt | <0.01 | <0.01 |
| Aluminum | 0.11 | 0.15 | Nickel | 0.18 | 0.20 |
| Arsenic | <0.03 | <0.03 | Oxygen | | <5 |
| Sodium | 60 | 6.9 | Copper | <0.1 | <0.1 |
| Potassium | 0.093 | 0.031 | Zinc | <0.1 | <0.1 |
| Magnesium | 0.023 | <0.01 | Zirconium | <0.01 | <0.01 |
| Carbon | | 49 | Niobium | <0.01 | <0.01 |
| Titanium | 1.4 | 0.60 | Molyb- | <0.01 | <0.01 |
| | | | denum | | |
| Vanadium | 0.021 | 0.061 | Indium | <0.05 | <0.05 |
| Chromium | 0.074 | 0.061 | Tantalum | <1 | <1 |
| Manganese | 0.027 | 0.019 | Nitrogen | | <5 |

### Example 3

A similar experiment was performed as described in Example 2, but the amount of silicon fines added was increased to equal to the amount of silicon produced, resulting in an amount of silicon in the final products twice that produced from the silicon fluoride/sodium reaction, equivalent to a production of silicon that is 200% of normal. The silicon fines were melt consolidated into an ingot.

### Example 4

Silicon fines from diamond wire cutting containing >2000 ppm weight of aluminum and several hundred ppm of other metallic impurities were mixed with pure sodium fluoride (<1 ppm of any individual impurity) in several ratios (1:5 and 1:3). The mixture was then loaded into a graphite crucible and externally heated to simulate the silicon fluoride/sodium reaction and exothermic characteristics. We found that in all cases, the silicon fines melt coalesce into a unique ingot. The purity of the Si and the purification factors are listed in Table 2 below.

TABLE 2

| | | | | Puri- |
|---|---|---|---|---|
| | Silicon Fines | Silicon Ingot - | Silicon Ingot - | fication |
| Impurity | (ppm) | Top (ppm) | Bottom (ppm) | Factor |
| Boron | 0.99 | 0.052 | 0.086 | >10 |
| Phosphorus | 1.8 | 0.3 | 0.32 | 6 |
| Aluminum | 2485 | 0.025 | 0.026 | ~105 |
| Arsenic | 0.32 | <0.03 | <0.03 | >10 |
| Sulfur | 1.7 | <0.03 | 0.039 | >50 |
| Sodium | 790 | 17 | 11 | ~50 |
| Potassium | 2250 | 0.64 | 0.25 | >3500 |
| Magnesium | 25 | <0.01 | <0.01 | >2500 |
| Calcium | 250 | <0.1 | <0.01 | >2500 |
| Titanium | 14 | 0.025 | 0.035 | 400 |
| Vanadium | <0.05 | <0.01 | <0.01 | N/A |
| Chromium | 1.5 | 0.01 | 0.016 | ~100 |
| Manganese | 45 | 0.17 | 0.076 | ~260 |
| Iron | 210 | 0.99 | 0.77 | ~200 |
| Cobalt | 0.41 | <0.01 | <0.01 | >50 |
| Nickel | 17 | 0.058 | 0.15 | ~100 |
| Copper | 4 | <0.1 | 0.22 | ~20 |
| Zirconium | 2.2 | <0.01 | <0.01 | >200 |
| Yttrium | 1.2 | <0.01 | <0.01 | >100 |
| Other TM | <0.05 to <0.5 | <0.03 to <0.1 | <0.03 to <0.1 | N/A |

### Example 5

Similar procedures as Example 2 and Example 3 were performed using silicon agglomerates obtained by drying of silicon waste fines from diamond wire cutting, but without pelletizing the silicon fines with sodium fluoride. These silicon agglomerates, known to contain up to 20 wt. % of silica, were co-fed into reactor 300 as descripted in Example 2 and were incorporated into the reaction products.

### Example 6

Similar procedure as Example 4 was performed using waste silicon fines from slicing wafers with silicon carbide slurries. When silicon fines with up to 5 wt. % silicon carbide fines were mixed with sodium fluoride and heated to temperatures above 1420° C., the silicon fines melted but did not coalesce in the molten sodium fluoride or magnesium fluoride; instead, they formed a cemented mass of silicon, silicon carbide, and sodium fluoride. Therefore, an efficient pre-separation step may be advantageous to completely remove silicon carbide from silicon before melt consolidation of silicon in fluoride melt.

### Example 7

A similar procedure as Example 4 was performed using pre-oxidized silicon fines that resulted from grinding silicon containing some organic species, such as surfactants, dispersants and other agents added to help the cutting or grinding. The peroxidation may be advantageous to remove carbon species. The silicon was then mixed with sodium fluoride in a 1:3 ratio and heated above the melting point of silicon. The silicon coalesced into a unique pool.

### Example 8

A similar procedure as Example 4 was performed using silicon fines that resulted from crushed polycrystalline silicon. The silicon fines consolidated into an ingot.

### Example 9

A similar procedure as Example 4 was performed using silicon fines that resulted from grinded heavily doped silicon with arsenic (>1000 ppm) and phosphorus (>100 ppm). The silicon consolidated into an ingot.

Various examples have been described. These and other examples are within the scope of the following claims.

What is claimed is:

1. A system for manufacturing high purity solid silicon, comprising:
a reactor comprising:
one or more inlets configured to receive a silicon tetrahalide, a reducing agent, and recycled silicon particles; and
a reactor chamber configured to react the silicon tetrahalide and the reducing agent to produce fresh silicon, a halide salt, and reaction heat, wherein the reactor chamber heats the recycled silicon particles, the fresh silicon, and the halide salt using at least a portion of the reaction heat to form molten silicon and molten halide salt, wherein the molten silicon includes melted fresh silicon and melted recycled silicon particles; and
a cooling chamber configured to cool the molten silicon to form the solid silicon.

2. The system of claim 1, further comprising a silicon particle processing system comprising a pelletizer configured to pelletize silicon fines to form the recycled silicon particles and transport the recycled silicon particles to at least one of the inlets of the reactor.

3. The system of claim 2, further comprising:
a silicon casting system configured to shape the solid silicon to create solar grade silicon crystals, ingots, or wafers and the silicon fines; and
a silicon fines recycle stream configured to feed the silicon fines to the silicon particle processing system.

4. The system of claim 2, wherein the silicon particle processing system includes a pretreatment system configured to remove impurities through at least one of etching, selective oxidation, acid leaching, and washing.

5. The system of claim 2, wherein the pelletizer is further configured to:
receive a binder comprising halide salt particles; and
pelletize the silicon fines with the halide salt particles to form the recycled silicon particles.

6. The system of claim 1, wherein the solid silicon and the recycled silicon particles include boron and phosphorus concentrations less than about 1 part per million weight.

7. The system of claim 1, wherein the reducing agent is at least one of lithium, sodium, potassium, and magnesium.

8. The system of claim 1, wherein the solid silicon is solar grade silicon.

9. A method for producing high purity solid silicon, comprising:
receiving, by a reaction chamber, a silicon tetrahalide, a reducing agent, and recycled silicon particles;
reacting, in the reaction chamber, the silicon tetrahalide and the reducing agent to produce fresh silicon, a halide salt, and reaction heat;
heating, in the reaction chamber, the recycled silicon particles, the fresh silicon, and the halide salt using at least a portion of the reaction heat to form molten silicon and molten halide salt, wherein the molten silicon includes melted fresh silicon and melted recycled silicon particles; and
cooling, in a cooling chamber, the molten silicon to produce the solid silicon.

10. The method of claim 9, further comprising pelletizing, using a pelletizer, silicon fines to form the recycled silicon particles.

11. The method of claim 10, further comprising:
shaping the solid silicon to create solar grade silicon crystals, solar grade silicon ingots, solar grade silicon wafers and the silicon fines;
purifying the silicon fines; and
feeding the purified silicon fines to the pelletizer.

12. The method of claim 11, wherein purifying the silicon fines comprises at least one of etching, selective oxidation, acid leaching, or washing.

13. The method of claim 11, further comprising pelletizing the silicon fines with a binder comprising halide salt particles to form the recycled silicon particles.

14. The method of claim 13, wherein the silicon fines and the molten salt particles are pelletized at a molar ratio of about 2:1 to about 5:1.

15. The method of claim 9, further comprising feeding the silicon tetrahalide from a silicon tetrahalide source, the reducing agent from a reducing agent source, and the recycled silicon particles from the silicon particle source.

16. The method of claim 10, wherein at least a portion of the silicon fines are supplied from an external silicon fines source.

17. The method of claim 9, further comprising allowing the molten silicon to solidify and crystallize.

18. The method of claim 9, wherein the solid silicon and the recycled silicon particles include boron and phosphorus concentrations less than about 1 part per million weight.

19. The method of claim 9, wherein the reducing agent is at least one of lithium, sodium, potassium, and magnesium.

20. The method of claim 9, further comprising:
heating the reaction chamber to a first temperature prior to receiving the reducing agent, wherein the first temperature is between a melting point of the reducing agent and a melting point of the silicon; and
heating the recycled silicon particles, the fresh silicon, and the halide salt to a second temperature above the melting point of the silicon using the at least a portion of the reaction heat.

21. The method of claim 20, wherein the molten silicon is cooled to a third temperature that is less than the melting point of the silicon and greater than the melting point of the halide salt prior to removing the molten halide salt.

22. The method of claim 21, wherein the solid silicon is solar grade silicon.
